(19) United States
(12) Patent Application Publication
(10) Pub. No.: US 2008/0164583 A1
(43) Pub. Date: Jul. 10, 2008

(54) CHIP PACKAGE CAPABLE OF MINIMIZING ELECTRO-MAGNETIC INTERFERENCE

(75) Inventors: Jiung-Yue Tien, Taichung County (TW); Ming-Te Tu, Taichung County (TW); Chin-Ching Huang, Taichung County (TW)

Correspondence Address: BROWDY AND NEIMARK, P.L.L.C.;624 NINTH STREET, NW, SUITE 300, WASHINGTON, DC, 20001-5303, US

(73) Assignee: Lingsen Precision Industries, Ltd., Taichung (TW)

(21) Appl. No.: 11/764,530

(22) Filed: Jun. 18, 2007

(30) Foreign Application Priority Data
Jan. 4, 2007 (TW) 96200163

(51) Int. Cl. H01L 23/552

(52) U.S. Cl. 257/659; 257/E23.114

(57) ABSTRACT

A cap package includes a substrate on which a chip is mounted. A cap is made of silicon doped with non-metal dopant. The cap is capped on the substrate to define with the substrate an accommodation chamber that receives the chip inside. The chip is electrically connected with a conducting portion of the substrate which is grounded.

### BACKGROUND OF THE INVENTION

1. Field of the Invention

The present invention relates generally to cap packages for packing chips and more particularly, to a cap package that can minimize the electro-magnetic interference.

2. Description of the Related Art

Cap package is intensively used in the fabrication of electronic products to protect electronic components. In a conventional cap package manufacturing process, a metal cap is used for cap package, achieving component protection function. However, shape forming from a single metal plate to a desired profile of metal cap is relatively difficult in manufacturing. Normally, a metal cap in a cap package is made by joining multiple metal elements together. This manufacturing procedure is time-consuming. Further, the conventional cap package can hardly isolate electromagnetic interference. The electronic component, e.g. chip, encapsulated in the cap package may be interfered with electromagnetic noises easily, thereby lowering the working efficiency, i.e., the shielding effectiveness of the conventional cap package is low.

Therefore, it is desirable to provide a cap package that eliminates the aforesaid drawbacks.

### SUMMARY OF THE INVENTION

The present invention has been accomplished in view of the above-noted circumstances. It is therefore one objective of the present invention to provide a cap package, which can minimize the electromagnetic interference.

To achieve this objective of the present invention, the cap package provided by the present invention comprises a substrate on which a chip is mounted. A cap, which is made of silicon doped with non-metal dopant, for example the group 3A or group 5A elements, is capped on the substrate to define with the substrate an accommodation chamber that receives the chip inside. The invention uses a semiconductor material to make a non-metal cap electrically conductive. By means of electrically connecting the cap to a conducting portion of the substrate, which is grounded, the cap package of the present invention can effectively minimize the electromagnetic interference.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a schematic drawing showing a silicon cap for the cap package according to a first preferred embodiment of the present invention;

FIG. 2 is a schematic drawing showing that the silicon cap of FIG. 1 is doped with dopant by ion implantation;

FIG. 3 is a schematic drawing showing the cap package in accordance with the first preferred embodiment of the present invention, and

FIG. 4 is a schematic drawing showing the cap package in accordance with a second preferred embodiment of the present invention.

### DETAILED DESCRIPTION OF THE INVENTION

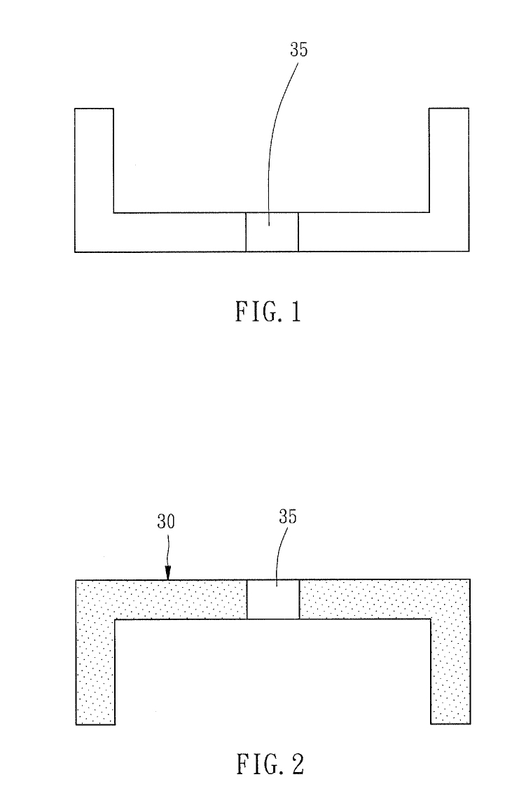

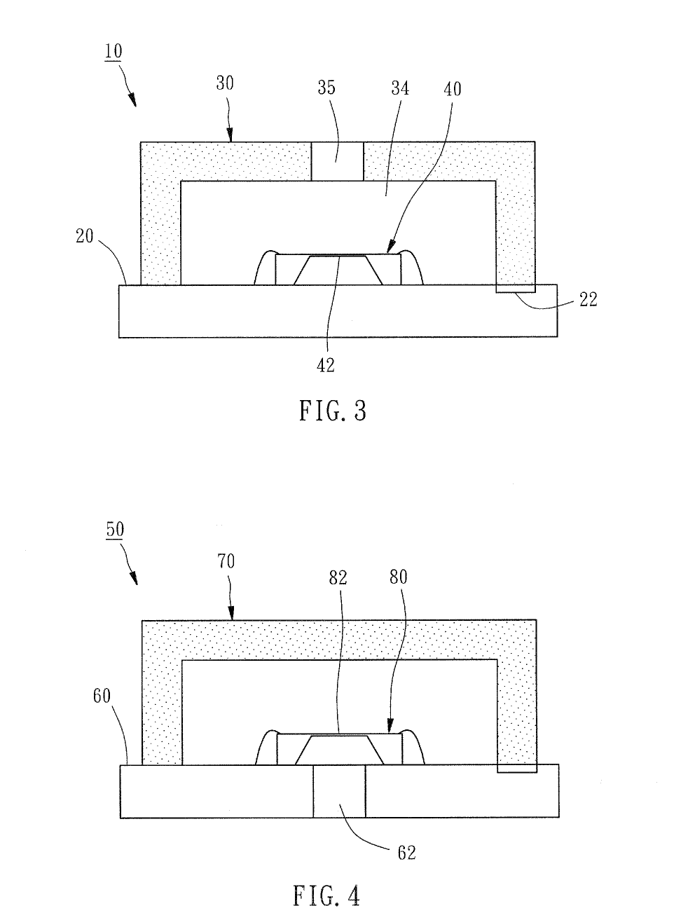

As shown in FIGS. 1-3, a cap package 10 in accordance with a first preferred embodiment of the present invention comprises a substrate 20, a cap 30 and a chip 40.

The substrate 20 has a conducting portion 22 electrically connected to the cap 30 and grounded.

The cap 30 is made of silicon that is doped with non-metal dopant by ion implantation. According to this embodiment, the cap 30 is a P-type semiconductor made of silicon doped with group 3A elements. The cap 30 has a resistivity smaller than 10² Ωm (ohm-meter). The cap 30 is capped on the substrate 20, defining an accommodation chamber 34. The cap 30 has an opening 35.

The chip 40 is installed on the substrate 20 and located inside the accommodation chamber 32. The chip 40 has an action zone 42 corresponding to the opening 34. The action zone 42 is a thin film in this preferred embodiment at the center of the chip 40.

The cap 30 of the cap package 10 is grounded to isolate external EMI (Electro-Magnetic Interference), prohibiting external electromagnetic noises from entering the accommodation chamber 32 to interfere with the chip 40. Therefore, the cap package 10 of the present invention effectively isolates electromagnetic interference, i.e., the invention eliminates the drawbacks of the conventional cap package.

FIG. 4 illustrates a cap package 50 in accordance with a second preferred embodiment of the present invention. Similar to the aforesaid first embodiment, the cap package 50 is comprised of a substrate 60, a cap 70 and a chip 80. According to this embodiment, the substrate 60 has an opening 62 corresponding to the action zone 82 of the chip 80, and the cap 70 fully shields the chip 80. In addition, the cap 70 is an N-type semiconductor made of silicon doped with group 5A elements.

Except the opening 62 at the substrate 60 to substitute for the opening 35 at the cap 30 in the aforesaid first embodiment, the cap package 50 of the second embodiment of the present invention has the same features of the aforesaid first embodiment. Therefore, this second embodiment achieves the same effect as the aforesaid first embodiment.

As indicated above, the cap package of the present invention uses a semiconductor material to make a non-metal cap electrically conductive, so that the cap package of the present invention can effectively minimize the electromagnetic interference, thereby eliminating the drawbacks of the prior art cap package using a metal cap.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A cap package comprising:
a substrate;
a cap made of silicon doped with non-metal dopant and capped on the substrate to define with the substrate an accommodation chamber; and
a chip mounted on the substrate and located inside the accommodation chamber.

2. The cap package as claimed in claim 1, wherein the cap has a resistivity smaller than 10² ΩM.

3. The cap package as claimed in claim 1, wherein the cap is a P-type semiconductor made of silicon doped with group 3A element.

4. The cap package as claimed in claim 1, wherein the cap is an N-type semiconductor made of silicon doped with group 5A element.

5. The cap package as claimed in claim 1, wherein the substrate has a conducting portion electrically connected to the cap.

6. The cap package as claimed in claim 5, wherein the conducting portion of the substrate is grounded.

7. The cap package as claimed in claim 1, wherein the cap is doped with non-metal dopant by means of ion implantation.

8. The cap package as claimed in claim 1, wherein the cap has an opening;
the chip has an action zone corresponding to the opening.

9. The cap package as claimed in claim 1, wherein the substrate has an opening; the chip has an action zone corresponding to the opening.
